(19) United States
(12) Patent Application Publication
(10) Pub. No.: US 2012/0273800 A1
(43) Pub. Date: Nov. 1, 2012

(54) COMPOSITE SUBSTRATE HAVING SINGLE-CRYSTAL SILICON CARBIDE SUBSTRATE

(75) Inventors: Tsutomu Hori, Itami-shi (JP); Shin Harada, Osaka-shi (JP); Hiroki Inoue, Itami-shi (JP); Makoto Sasaki, Itami-shi (JP); Satomi Itoh, Osaka-shi (JP); Yasuo Namikawa, Osaka-shi (JP)

(73) Assignee: SUMITOMO ELECTRIC INDUSTRIES, LTD., Osaka (JP)

(21) Appl. No.: 13/395,494

(22) PCT Filed: Jun. 17, 2011
(86) PCT No.: PCT/JP2011/063951

§ 371 Date: Mar. 12, 2012

(30) Foreign Application Priority Data
Oct. 19, 2010 (JP) 2010-234238

(51) Int. Cl. H01L 29/24

(52) U.S. Cl. 257/77; 257/E29.104

(57) ABSTRACT

A first vertex of a first single-crystal silicon carbide substrate and a second vertex of a second single-crystal silicon carbide substrate abut each other such that a first side of the first single-crystal silicon carbide substrate and a second side of the second single-crystal silicon carbide substrate are aligned. In addition, at least a part of the first side and at least a part of the second side abut on a third side of a third single-crystal silicon carbide substrate. Thus, in manufacturing a semiconductor device including a composite substrate, process fluctuations caused by a gap between the single-crystal silicon carbide substrates can be suppressed.

### TECHNICAL FIELD

The present invention relates to a composite substrate having a single-crystal silicon carbide substrate, and particularly to a composite substrate having a plurality of single-crystal silicon carbide substrates.

### BACKGROUND ART

A compound semiconductor has recently increasingly been adopted for a semiconductor substrate used for manufacturing a semiconductor device. For example, single-crystal silicon carbide has a bandgap wider than single-crystal silicon that has more commonly been used. Therefore, a semiconductor device including a single-crystal silicon carbide substrate is advantageous in a high breakdown voltage, a low ON resistance and less lowering in characteristics in an environment at a high temperature.

In order to efficiently manufacture a semiconductor device, a substrate is required to have a size not smaller than a certain size. According to U.S. Pat. No. 7,314,520 (PTL 1), a silicon carbide substrate not smaller than 76 mm (3 inches) can be manufactured.

### CITATION LIST

### Patent Literature

PTL 1: U.S. Pat. No. 7,314,520

### SUMMARY OF INVENTION

### Technical Problem

A size of a single-crystal silicon carbide substrate industrially remains as small as approximately 100 mm (4 inches) and hence it has not yet been able to efficiently manufacture a semiconductor device with the use of a large-sized substrate. In making use of characteristics of a plane other than a (0001) plane in particular in hexagonal silicon carbide, the problem above is particularly serious, which will be described below.

A single-crystal silicon carbide substrate having fewer defects is normally manufactured by cutting an ingot obtained by (0001) plane growth in which stacking faults are less likely. Therefore, a substrate having a plane orientation other than the (0001) plane is cut in non-parallel to a growth surface. It is thus difficult to secure a sufficient size of a substrate or a most part of an ingot cannot effectively be made use of. Thus, it is particularly difficult to efficiently manufacture a semiconductor device using a plane other than the (0001) plane of silicon carbide.

Instead of increase in size of a single-crystal silicon carbide substrate with such difficulties as above, use of a composite substrate having a plurality of single-crystal silicon carbide substrates and a base portion joined to each of them is possible. In many cases, a base portion high in crystal defect density to some extent does not give rise to a problem, and therefore a large-sized base portion can relatively easily be prepared. Then, a composite substrate can be increased in size as necessary, by increasing the number of single-crystal silicon carbide substrates joined to the base portion.

Though each of the single-crystal silicon carbide substrates and the base portion are joined to each other in the composite substrate above, adjacent single-crystal silicon carbide substrates may not be joined to each other or joint therebetween may be insufficient. Consequently, a gap may be formed between adjacent single-crystal silicon carbide substrates. Presence of this gap may become a factor for process fluctuations in manufacturing a semiconductor device including a composite substrate.

The present invention was made in view of the above-described problems, and an object of the present invention is to provide a composite substrate in which process fluctuations caused by a gap between single-crystal silicon carbide substrates can be suppressed in manufacturing a semiconductor device including the composite substrate.

### Solution to Problem

A composite substrate according to the present invention has a base portion and first to third single-crystal silicon carbide substrates. The first single-crystal silicon carbide substrate is provided on the base portion and has a first side extending from a first vertex having a first angle in planar view. The second single-crystal silicon carbide substrate is provided on the base portion and has a second side extending from a second vertex having a second angle, the sum of the first angle and the second angle being 180° in planar view. The third single-crystal silicon carbide substrate is provided on the base portion and has a third side connecting third and fourth vertices to each other in planar view. The first vertex and the second vertex abut each other such that the first side and the second side are aligned. In addition, at least a part of the first side abuts on the third side. Moreover, at least a part of the second side abuts on the third side.

According to the present composite substrate, since the first and second sides both abut on the third side, the first side and the second side are aligned with the third side serving as the reference. Namely, there is no misalignment between the first and second sides. Therefore, formation of a large gap between the single-crystal silicon carbide substrates due to this misalignment can be prevented. Thus, in manufacturing a semiconductor device including a composite substrate, process fluctuations caused by a gap between single-crystal silicon carbide substrates can be suppressed.

Preferably, a gap is provided among the first to third single-crystal silicon carbide substrates, and the composite substrate further includes a closing portion closing the gap.

Thus, in manufacturing a composite substrate, working accurate enough to form no gap between single-crystal silicon carbide substrates does not have to be performed. Therefore, a composite substrate can be suitable for mass production. In addition, since this gap is closed by a closing portion, accumulation of foreign matters in a gap can be prevented. Thus, in manufacturing a semiconductor device including a composite substrate, process fluctuations caused by a gap between single-crystal silicon carbide substrates can further be suppressed.

The closing portion may close the gap, within the gap. Thus, the gap can be closed without affecting a structure outside the gap.

The composite substrate may further include a coating layer formed on the first to third single-crystal silicon carbide substrates, and the coating layer includes the closing portion. Thus, a desired coating layer can be formed on the first to third single-crystal silicon carbide substrates, and at the same time a gap can be closed.

Preferably, the closing portion is made of silicon carbide. Thus, a gap between single-crystal silicon carbide substrates can be closed with a material the same as that for a single-crystal silicon carbide substrate.

### Advantageous Effects of Invention

As is clear from the description above, according to the present invention, in manufacturing a semiconductor device including a composite substrate having a plurality of single-crystal silicon carbide substrates, process fluctuations caused by a gap between silicon carbide substrates can be suppressed.

### BRIEF DESCRIPTION OF DRAWINGS

FIG. 1 is a plan view schematically showing a construction of a composite substrate in a first embodiment of the present invention.

FIG. 2 is a partial enlarged view of FIG. 1.

FIG. 3 is a schematic partial cross-sectional view along the line in FIG. 2.

FIG. 4 is a partial cross-sectional view schematically showing one step in a method of manufacturing a composite substrate in the first embodiment of the present invention.

FIG. 5 is a plan view showing an ideal construction of a composite substrate in a first comparative example.

FIG. 6 is a plan view showing an actual construction of a composite substrate in the first comparative example.

FIG. 7 is a partial enlarged view of FIG. 5.

FIG. 8 is a plan view schematically showing a construction of a composite substrate in a second embodiment of the present invention.

FIG. 9 is a partial enlarged view of FIG. 8.

FIG. 10 is a plan view showing an ideal construction of a composite substrate in a second comparative example.

FIG. 11 is a plan view showing the actual construction of the composite substrate in the first comparative example.

FIG. 12 is a cross-sectional view schematically showing a construction of a composite substrate in a third embodiment of the present invention.

FIG. 13 is a plan view schematically showing one step in a method of manufacturing a composite substrate in the third embodiment of the present invention.

FIG. 14 is a partial cross-sectional view schematically showing a construction of a composite substrate in a fourth embodiment of the present invention.

FIG. 15 is a partial cross-sectional view schematically showing a construction of a composite substrate in a fifth embodiment of the present invention.

FIG. 16 is a partial cross-sectional view schematically showing one step in a method of manufacturing a semiconductor device in the fifth embodiment of the present invention.

FIG. 17 is a partial cross-sectional view schematically showing a construction of a semiconductor device in a sixth embodiment of the present invention.

FIG. 18 is a schematic flowchart of a method of manufacturing a semiconductor device in the sixth embodiment of the present invention.

FIG. 19 is a partial cross-sectional view schematically showing a first step in the method of manufacturing a semiconductor device in the sixth embodiment of the present invention.

FIG. 20 is a partial cross-sectional view schematically showing a second step in the method of manufacturing a semiconductor device in the sixth embodiment of the present invention.

FIG. 21 is a partial cross-sectional view schematically showing a third step in the method of manufacturing a semiconductor device in the sixth embodiment of the present invention.

FIG. 22 is a partial cross-sectional view schematically showing a fourth step in the method of manufacturing a semiconductor device in the sixth embodiment of the present invention.

FIG. 23 is a partial cross-sectional view schematically showing a fifth step in the method of manufacturing a semiconductor device in the sixth embodiment of the present invention.

### DESCRIPTION OF EMBODIMENTS

An embodiment of the present invention will be described hereinafter with reference to the drawings.

### First Embodiment

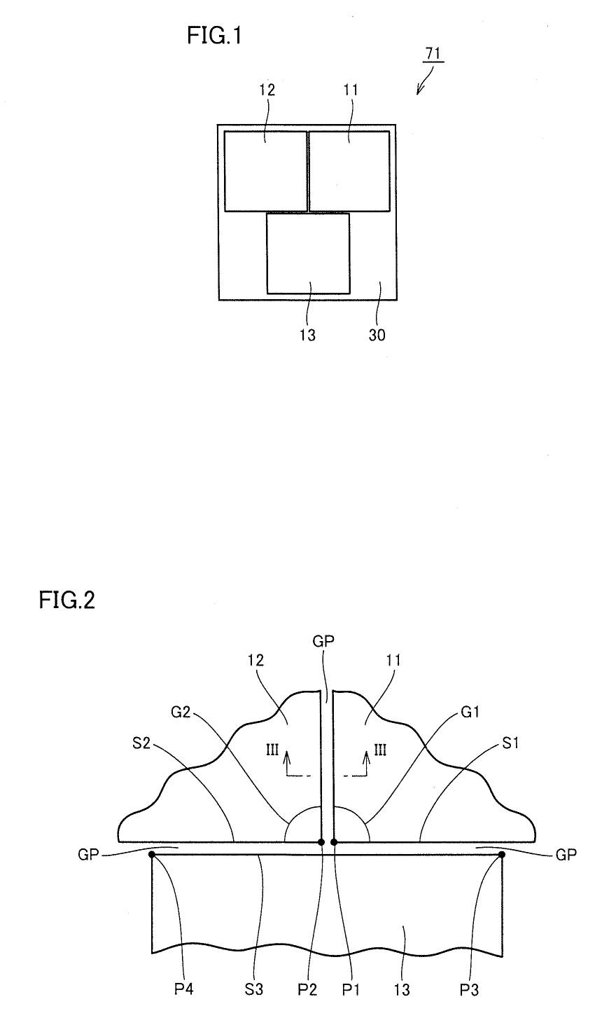

As shown in FIG. 1, a composite substrate 71 in the present embodiment has a base portion 30 and SiC substrates 11 to 13 provided on base portion 30. Each of SiC substrates 11 to 13 and base portion 30 are joined to each other.

Each of SiC substrates 11 to 13 is a single-crystal silicon carbide substrate. Preferably, a front surface of SiC substrates 11 to 13 (an illustrated surface) is a surface planarized by polishing. In addition, preferably, each of SiC substrates 11 to 13 is a substrate made of substantially the same material and having substantially the same plane orientation.

In the present embodiment, base portion 30 is a substrate made of silicon carbide. Preferably, at least a portion of base portion 30 facing each of SiC substrates 11 to 13 has a crystal structure corresponding to a crystal structure of SiC substrates 11 to 13. Specifically, a portion of base portion 30 facing each of SiC substrates 11 to 13 is a portion epitaxially grown on SiC substrates 11 to 13. Base portion 30 may include a portion having a single-crystal structure. This portion may be lower in crystallinity than SiC substrates 11 to 13. In addition, this portion may be higher in micropipe density than SiC substrates 11 to 13. Further, preferably, base portion 30 is higher in impurity concentration than SiC substrates 11 to 13. Base portion 30 has a thickness, for example, of 400 μm.

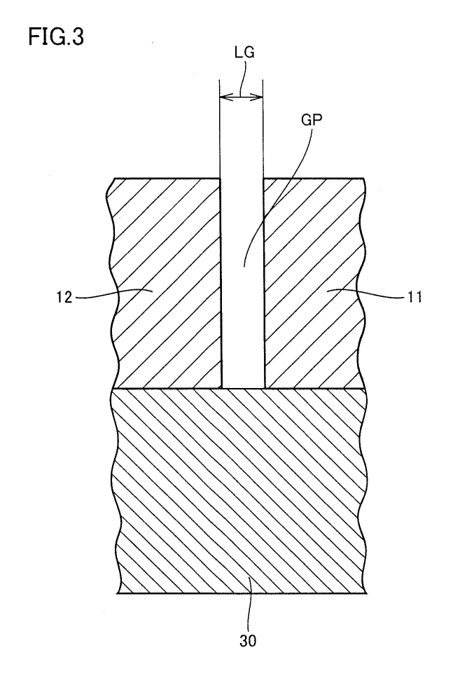

As shown further in FIGS. 2 and 3, SiC substrate 11 (a first single-crystal silicon carbide substrate) has a side S1 (a first side) extending from a vertex P1 (a first vertex) having an angle G1 (a first angle) in planar view (FIG. 2). SiC substrate 12 (a second single-crystal silicon carbide substrate) has a side S2 (a second side) extending from a vertex P2 (a second vertex) having an angle G2 (a second angle), the sum of angle G1 and angle G2 being 180° in planar view. SiC substrate 13 (a third single-crystal silicon carbide substrate) has a side S3 (a third side) connecting vertices P3 and P4 (third and fourth vertices) to each other in planar view.

Vertices P1 and P2 abut each other such that sides 51 and S2 are aligned as shown in FIG. 2. In addition, at least a part of side S1 abuts on side S3. Moreover, at least a part of side S2 abuts on side S3. No other vertex is arranged in the vicinity of where vertices P1 and P2 abut each other, and a gap GP has a T-shape.

Since accuracy in working of each member and accuracy in arrangement of each member are actually limited, it is difficult to completely eliminate a gap among SiC substrates 11 to 13 and small gap GP is normally produced among SiC substrates 11 to 13. A width LG of this gap is preferably not greater than 100 μm at the minimum, more preferably not greater than 100 μm on average, and further preferably not greater than 100 μm at the maximum. This gap GP may be formed also between vertices P1 and P2 and between each of sides S1 and S2 and side S3.

In the present embodiment, each of angles G1 and G2 above is set to 90°. More specifically, each of SiC substrates 11 to 13 has a rectangular two-dimensional shape, and it may have, for example, a square two-dimensional shape, as shown in FIG. 1. A length of one side of this square has an upper limit in terms of manufacturing techniques in mass production of SiC substrates 11 to 13, that is, single-crystal silicon carbide substrates. By way of example of a dimension, each of SiC substrates 11 to 13 has a two-dimensional shape of a square of 20×20 mm and a thickness of 400 μm.

A method of manufacturing composite substrate 71 will now be described.

Initially, each of SiC substrates 11 to 13 is placed on base portion 30 as shown in FIG. 1. A surface of each of SiC substrates 11 to 13 facing base portion 30 is preferably a surface formed by slicing, that is, a surface formed by slicing but not polished thereafter (what is called an as-slice surface). Such a surface may have moderate irregularities as a result of slicing. It is noted that a surface of base portion 30 facing SiC substrates 11 to 13 may be an as-slice surface.

Then, arrangement of SiC substrates 11 to 13 is adjusted such that gap GP (FIG. 2) among SiC substrates 11 to 13 is minimized. Specifically, each of sides S1 and S2 is caused to abut on side S3, and vertices P1 and P2 are caused to abut each other. This operation may be performed, for example, by performing an operation for pressing an upper side of SiC substrate 11 and a lower side of SiC substrate 13 toward each other, an operation for pressing an upper side of SiC substrate 12 and the lower side of SiC substrate 13 toward each other, and an operation for pressing a right side of SiC substrate 11 and a left side of the SiC substrate toward each other in FIG. 1.

Then, an atmosphere is set to an atmosphere obtained by reducing a pressure of an ambient atmosphere. A pressure of the atmosphere is set preferably to be higher than 10⁻¹ Pa and lower than 10⁴ Pa. It is noted that the atmosphere above may be an inert gas atmosphere. As an inert gas, for example, a noble gas such as He or Ar, a nitrogen gas, or a gas mixture of a noble gas and the nitrogen gas can be employed. In addition, a pressure of the atmosphere is preferably not higher than 50 kPa and more preferably not higher than 10 kPa.

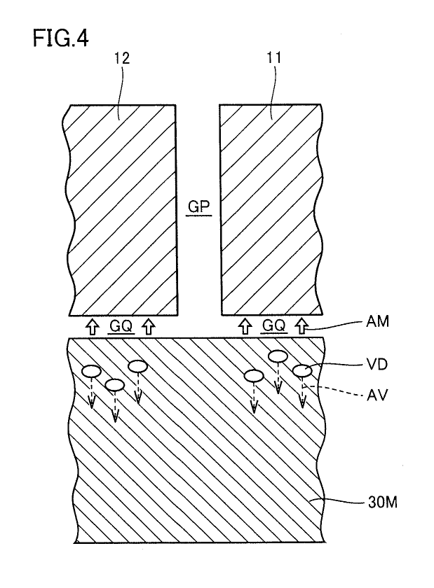

As shown in FIG. 4, at this time point, each of SiC substrates 11 to 13 (SiC substrate 13 not shown) and base portion 30 are merely placed as layered, and they have not yet been joined to each other. Between each of SiC substrates 11 to 13 and base portion 30, due to presence of small irregularities on a back surface (a surface facing base portion 30) of each of SiC substrates 11 to 13 or due to small irregularities on a front surface (a surface facing SiC substrates 11 to 13) of base portion 30, a gap GQ is microscopically provided.

Then, SiC substrates 11 to 13 and base portion 30 are heated. This heating is carried out such that a temperature of base portion 30 reaches a temperature at which silicon carbide can sublimate, for example, a temperature not lower than 1800° C. and not higher than 2500° C. and more preferably not lower than 2000° C. and not higher than 2300° C. A heating time period is set, for example, to 1 to 24 hours.

In addition, heating above is carried out such that a temperature of each of SiC substrates 11 to 13 is lower than a temperature of base portion 30. Namely, such a temperature gradient that a temperature decreases from bottom to above in FIG. 4 is formed. This temperature gradient between each of SiC substrates 11 to 13 and base portion 30 is preferably not smaller than 1° C./cm and not greater than 200° C./cm and more preferably not smaller than 10° C./cm and not greater than 50° C./cm. As such a temperature gradient is provided in a direction of thickness (a vertical direction in FIG. 4), a temperature on a base portion 30 side (a lower side in FIG. 4) becomes higher than a temperature on a side of each of SiC substrates 11 to 13 (an upper side in FIG. 4). Consequently, sublimation of silicon carbide into gap GQ is more likely from base portion 30 than from SiC substrates 11 to 13. In contrast, recrystallization reaction of a sublimation gas in gap GQ is more likely on SiC substrates 11 to 13 than on base portion 30. Consequently, mass transfer of silicon carbide due to sublimation and recrystallization occurs in gap GQ, as shown with an arrow AM in the figure.

With mass transfer shown with arrow AM described above, gap GQ is divided into a large number of voids VD, and voids VD move as shown with an arrow AV pointing in a direction reverse to arrow AM. In addition, with this mass transfer, base portion 30 grows again on SiC substrates 11 to 13. Namely, base portion 30 is formed again through sublimation and recrystallization. This formation again gradually proceeds from a region close to SiC substrates 11 to 13. Namely, a portion of base portion 30 located above the back surface (the lower surface in FIG. 4) of SiC substrates 11 to 13 epitaxially grows toward this back surface. Preferably, entire base portion 30 is formed again.

As a result of formation again above, base portion 30 transforms to a portion including a portion having a crystal structure corresponding to the crystal structure of SiC substrates 11 to 13. In addition, a space corresponding to gap GQ becomes voids VD in base portion 30 and thereafter most of them escape to the outside of base portion 30 (downward in FIG. 4). Consequently, composite substrate 71 (FIG. 1) having SiC substrates 11 to 13 of which back surfaces are joined to base portion 30 is obtained.

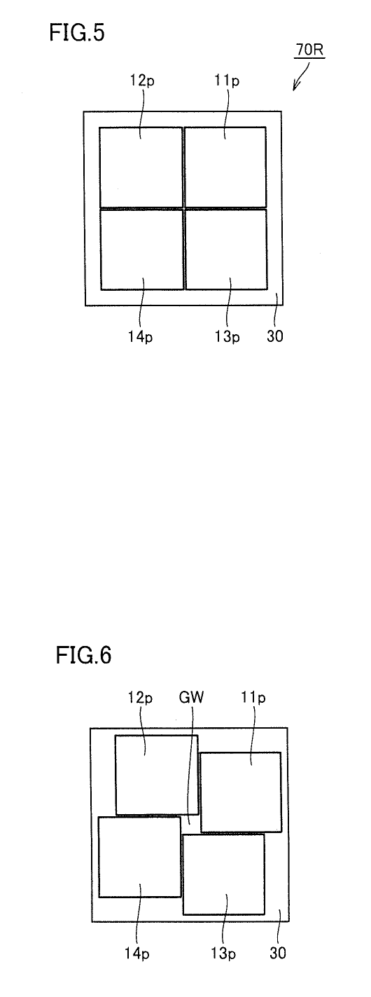

A composite substrate 70R (FIG. 5) in a comparative example will now be described. Composite substrate 70R has SiC substrates 11p to 14p. SiC substrates 11p to 14p are similar to SiC substrates 11 to 13 described above. Ideally, SiC substrates 11p to 14p have matrix arrangement as shown in FIG. 5. Namely, a small gap among SiC substrates 11p to 14p forms a cross shape at a position where respective vertices of SiC substrates 11p to 14p, that is, four vertices, meet one another. Actually, however, instead of such a cross-shaped gap, a large gap GW (FIG. 6) is often formed. A cause therefor will be described below.

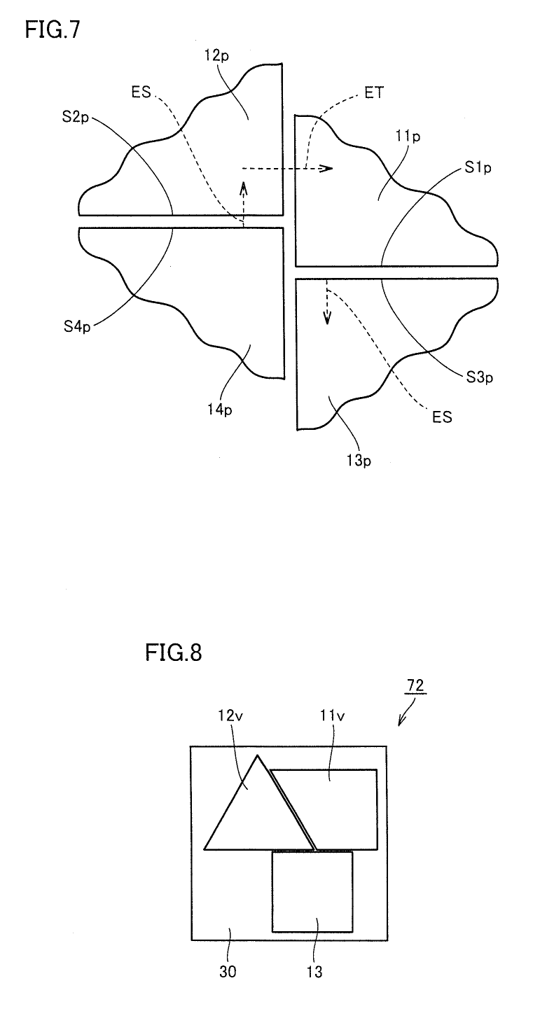

As shown in FIG. 7, sides S3p and S4p are sides of SiC substrates 13p and 14p, respectively. Namely, sides S3p and S4p belong to different SiC substrates, respectively. Therefore, though sides S3p and S4p are ideally arranged on a line in the present comparative example, actually, displacement by an error ES from arrangement on a line is caused. When a side S1p abuts on side S3p and a side S2p abuts on side S4p in the presence of such displacement, misalignment is created between sides S1p and S2p. When positions of SiC substrates 11p and 12p that abut each other are displaced by an error ET with respect to positions of SiC substrates 13p and 14p that abut each other in the presence of this misalignment, large gap GW (FIG. 6) is generated.

In contrast, according to present composite substrate 71, since sides S1 and S2 both abut on single side S3 as shown in FIG. 2, side S1 and side S2 are aligned with side S3 serving as the reference. Namely, there is no misalignment between sides S1 and S2. Therefore, even though sides S1 and S2 that abut each other are displaced along side S3, formation of a large gap among SiC substrates 11 to 13 can be prevented. Thus, in using composite substrate 71, adverse influence by a large gap among SiC substrates 11 to 13 can be lessened.

In addition, since base portion 30 is made of silicon carbide, various physical properties of each of SiC substrates 11 to 13 and base portion 30 can be close. Moreover, base portion 30 can be used as a portion composed of silicon carbide, of a semiconductor device manufactured by using composite substrate 71.

Base portion 30 may be higher in micropipe density than each of SiC substrates 11 to 13. Thus, base portion 30 difficult to form because of its size larger than each of SiC substrates 11 to 13 can more readily be formed.

Preferably, base portion 30 is higher in impurity concentration than each of SiC substrates 11 to 13. Namely, relatively, impurity concentration in base portion 30 is high, and impurity concentration in SiC substrates 11 to 13 is low. As impurity concentration in base portion 30 is high, resistivity of base portion 30 can be low and hence base portion 30 can be used as a portion low in resistivity in a semiconductor device. In addition, as impurity concentration in SiC substrates 11 to 13 is low, crystal defects thereof can more readily be reduced. It is noted that, for example, nitrogen (N), phosphorus (P), boron (B), or aluminum (Al) can be used as the impurity.

A preferred form of each of SiC substrates 11 to 13 (simply also referred to as an “SiC substrate”) will now be described below.

Silicon carbide in an SiC substrate preferably has a hexagonal crystal structure and more preferably has a 4H type or a 6H type. In addition, preferably, an off angle of a surface of the SiC substrate with respect to a (000-1) plane is not smaller than 50° and not greater than 65°. More preferably, an angle between an off orientation of the surface and a <1-100> direction is not greater than 5°. Further preferably, an off angle of the surface with respect to a (0-33-8) plane in the <1-100> direction is not smaller than −3° and not greater than 5°. As such a crystal structure is employed, channel mobility of a semiconductor device including composite substrate 71 can be enhanced.

It is noted that the “off angle of the surface with respect to a (0-33-8) plane in the <1-100> direction” refers to an angle formed between an orthogonal projection of a normal of the surface onto a projection surface where the <1-100> direction and a <0001> direction extend and a normal of the (0-33-8) plane, and the sign is positive when the orthogonal projection above is closer to parallel to the <1-100> direction, and the sign is negative when the orthogonal projection above is closer to parallel to the <0001> direction. Further, other than the above, as a preferred off orientation of the surface, such an off orientation that an angle with respect to a <11-20> direction of the SiC substrate is not greater than 5° can also be employed.

By way of specific example, an SiC substrate is prepared by cutting an SiC ingot grown on the (0001) plane in a hexagonal system along the (0-33-8) plane. A (0-33-8) plane side is used as a front surface, while a (03-38) plane side is used as a back surface (a surface to be joined to base portion 30). Thus, channel mobility on the surface can particularly be enhanced.

### Second Embodiment

As shown in FIG. 8, a composite substrate 72 in the present embodiment has SiC substrates 11v (the first single-crystal silicon carbide substrate) and 12v (the second single-crystal silicon carbide substrate) instead of SiC substrates 11 and 12 described above, respectively. SiC substrates 11v and 12v are substantially similar to SiC substrates 11 and 12, respectively, however, their two-dimensional shapes are different.

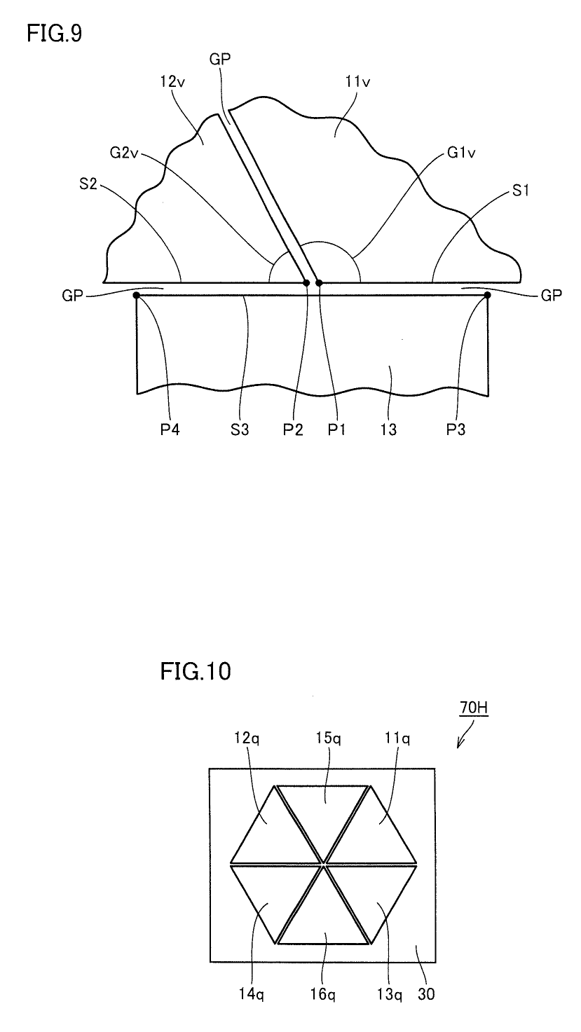

As shown in FIG. 9, SiC substrate 11v has side S1 extending from vertex P1 having an angle G1v (the first angle) in planar view. S1C substrate 12v has side S2 extending from vertex P2 having an angle G2v (the second angle), the sum of angle G1v and angle G2v being 180° in planar view. In the present embodiment, angle G1v is set to 120° and angle G2v is set to 60°. As shown in FIG. 8, SiC substrate 12v may have a two-dimensional shape of an equilateral triangle in planar view.

Since a construction other than the above is substantially the same as in the first embodiment described above, the same or corresponding elements have the same reference characters allotted and description thereof will not be repeated.

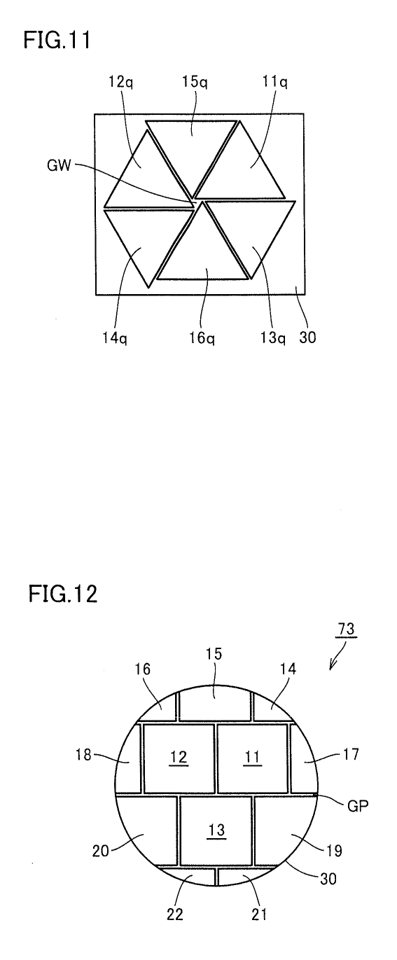

A composite substrate 70H (FIG. 10) in a comparative example will now be described. Composite substrate 70H has SiC substrates 11q to 16q. Each of SiC substrates 11q to 16q is similar to SiC substrate 12v described above. Ideally, SiC substrates 11q to 16q are arranged such that vertices, that is, six vertices each having an angle of 60°, abut one another as shown in FIG. 10. Namely, a small gap among SiC substrates 11q to 16q forms an asterisk shape at a position where respective vertices of SiC substrates 11q to 16q meet one another. Actually, however, due to an error in working or arrangement, instead of an asterisk-shaped gap, large gap GW (FIG. 11) is often formed as in the comparative example (FIG. 6).

In contrast, according to the present embodiment, as in the first embodiment, formation of a large gap described above can be prevented. In addition, in the present embodiment, in particular, SiC substrates 11v and 12v having vertices having angles of 120° and 60° respectively in planar view are employed. Namely, an SiC substrate having a vertex having an angle of which value is a multiple of 60° is employed. Thus, a substrate including a vertex having an angle of which value is a multiple of 60° may be useful in terms of symmetry, in a case where an SiC substrate has a hexagonal crystal structure, because the hexagonal system has six-fold symmetry, that is, symmetry with respect to rotation by 60°, and hence sides of an SiC substrate can readily crystallographically be equivalent.

### Third Embodiment

As shown in FIG. 12, a composite substrate 73 in the present embodiment further has SiC substrates 14 to 22 in addition to SiC substrates 11 to 13 in the first embodiment. SiC substrates 11 to 22 are shaped and arranged to have an annular outer periphery as a whole in planar view. In addition, in the present embodiment, base portion 30 has an outer periphery corresponding to this annular periphery. Namely, SiC substrates 11 to 22 are provided on base portion 30 so as to cover the entire surface of base portion 30 having an annular shape. It is noted that gap GP as in the first embodiment may be formed among SiC substrates 11 to 22.

A method of manufacturing composite substrate 73 will now be described.

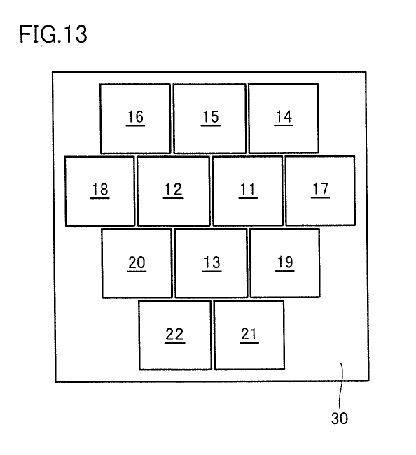

As shown in FIG. 13, sufficiently large base portion 30 having any outer peripheral shape is prepared. In addition, SiC substrates 11 to 13 as in the first embodiment are prepared and SiC substrates 14 to 22 are further prepared. Each of SiC substrates 11 to 22 may have a rectangular two-dimensional shape, and for example, may have a square two-dimensional shape as shown in FIG. 13. For example, each of SiC substrates 11 to 22 may have a two-dimensional shape of a 20-mm square.

Then, SiC substrates 11 to 22 are arranged on base portion 30. Positional relation among three SiC substrates 11 to 13 in this arrangement is as described in the first embodiment. Then, in a step similar to the heating step (FIG. 4) in the first embodiment, each of SiC substrates 11 to 22 is joined to base portion 30. Then, composite substrate 73 (FIG. 12) is obtained by removing an unnecessary outer peripheral portion and carrying out such working as making the outer periphery annular.

Since a construction other than the above is substantially the same as in the first embodiment described above, the same or corresponding elements have the same reference characters allotted and description thereof will not be repeated.

According to the present embodiment, an effect as in the first embodiment is obtained. In addition, as a result of removal of an unnecessary outer circumferential portion described above, a portion where base portion 30 is largely exposed, that is, a portion where difference in height from the surface of SiC substrates 11 to 13 is formed, can be removed.

### Fourth Embodiment

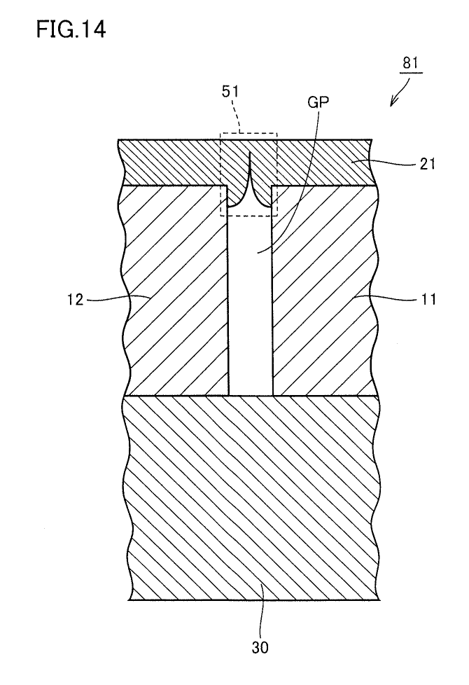

Referring to FIG. 14, a composite substrate 81 in the present embodiment has a coating layer 21 formed on SiC substrates 11 to 13 (SiC substrate 13 not shown) described above. Coating layer 21 includes a closing portion 51 closing gap GP. Closing portion 51 isolates a cavity from the outside world while leaving the cavity between closing portion 51 and base portion 30. In order to reliably carry out closing, coating layer 21 on SiC substrates 11 to 13 has a thickness preferably not smaller than 1/100 of a minimum value of a width of gap GP, more preferably not smaller than 1/100 of an average value of this width, and further preferably not smaller than 1/100 of a maximum value of this width. In addition, preferably, a surface of coating layer 21 (an upper surface in FIG. 14) is planarized, for example, by polishing by CMP.

Preferably, coating layer 21 is made of silicon carbide. In addition, preferably, at least a part of coating layer 21 is epitaxially grown on SiC substrates 11 to 13. This epitaxial growth includes not only growth perpendicular to the surface of SiC substrates 11 to 13, that is, growth in a vertical direction in FIG. 14, but also growth in a lateral direction. As a result of growth in this lateral direction, closing by closing portion 51 is achieved. In order to further reliably achieve closing, a starting point of epitaxial growth preferably includes an end portion of a side surface on a front surface side, in addition to the front surface (the upper surface in FIG. 14) of SiC substrates 11 to 13. A heating temperature necessary for epitaxial growth is, for example, not lower than 1550° C. and not higher than 1600° C.

Since a construction other than the above is substantially the same as in the first to third embodiments described above, the same or corresponding elements have the same reference characters allotted and description thereof will not be repeated.

According to the present embodiment, gap GP is provided among SiC substrates 11 to 13. Thus, in manufacturing composite substrate 81, accuracy high enough to form no gap GP among SiC substrates 11 to 13 is not required. Therefore, composite substrate 81 is suitable for mass production.

In addition, since this gap GP is closed by closing portion 51, accumulation of foreign matters in gap GP can be prevented. Thus, in using composite substrate 81, adverse influence by large gap GP among SiC substrates 11 to 13 can further be lessened. This adverse influence includes, for example, an abrasive remaining in gap GP during CMP, edge chipping of SiC substrates 11 to 13 during CMP, or in-plane variation in the step of applying a photoresist.

Further, gap GP can be closed simultaneously with formation of desired coating layer 21 on SiC substrates 11 to 13. Coating layer 21 can be used as a portion composed of silicon carbide in a semiconductor device manufactured by using composite substrate 81. Preferably, at least a part of coating layer 21 epitaxially grows on SiC substrates 11 and 12. Thus, a crystal structure of coating layer 21 can be optimized to a structure suitable for a semiconductor device.

### Fifth Embodiment

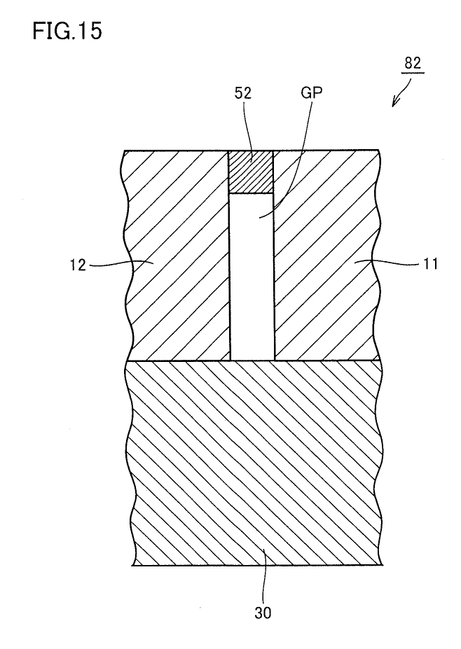

As shown in FIG. 15, a composite substrate 82 in the present embodiment has a closing portion 52. Closing portion 52 closes gap GP, within gap GP. In the present embodiment, closing portion 52 is made of silicon carbide.

Referring to FIG. 16, a method of manufacturing composite substrate 82 will be described. Initially, a composite substrate having gap GP as described in the first to third embodiments is prepared. Then, a cover 70 for temporarily closing gap GP is formed on SiC substrates 11 to 13 (SiC substrate 13 not shown). Cover 70 is formed, for example, as follows.

A resist liquid, which is a liquid containing an organic substance, is applied onto the surface of SiC substrates 11 to 13, as a fluid containing carbon element. The applied resist liquid is tentatively fired at 100 to 300° C. for 10 seconds to 2 hours. As the resist liquid is thus cured, a resist layer is formed. Then, this resist layer is subjected to heat treatment and carbonated, so that cover 70 is consequently formed. Conditions in heat treatment are such that an atmosphere is an inert gas or a nitrogen gas at a pressure not higher than an atmospheric pressure, a temperature is higher than 300° C. and lower than 1700° C., and a treatment time period is longer than 1 minute and shorter than 12 hours. When a temperature is 300° C. or lower, carbonation tends to be insufficient. In contrast, when a temperature is 1700° C. or higher, the surface of SiC substrates 11 to 13 tends to deteriorate. When a treatment time period is set to 1 minute or shorter, carbonation of the resist layer tends to be insufficient and treatment for a longer time period is preferred. This treatment time period shorter than 12 hours at the longest, however, is sufficient. It is noted that a thickness of the resist liquid above is preferably adjusted such that cover 70 has a thickness greater than 0.1 μm and smaller than 1 mm. When the thickness is 0.1 μm or smaller, cover 70 may be discontinuous above gap GP. Alternatively, when cover 70 has a thickness of 1 mm or greater, a time period required for subsequent removal of cover 70 becomes long.

Then, the composite substrate on which cover 70 has been formed as above is heated to a temperature at which silicon carbide can sublimate. This heating is carried out such that a temperature gradient is produced in a direction of thickness (a vertical direction in the figure), that is, such that a temperature on a side of SiC substrates 11 to 13 facing cover 70 (an upper side in FIG. 16) is lower than a temperature on a side of SiC substrates 11 to 13 facing base portion 30 (a lower side in FIG. 16). Such a temperature gradient can be obtained, for example, by carrying out heating such that a temperature of cover 70 is lower than a temperature of base portion 30.

As a result of this heating, mass transfer involved with sublimation occurs as shown with an arrow in the figure in closed gap GP, from a region at a relatively high temperature in a side surface of SiC substrates 11 to 13, which is close to base portion 30, to a region at a relatively low temperature, which is close to cover 70. With this mass transfer, in gap GP closed by cover 70, a sublimate is deposited on cover 70. As a result of this deposition, closing portion 52 (FIG. 15) is formed.

After closing portion 52 is formed, cover 70 is removed. Cover 70 can readily be removed by oxidizing carbon in cover 70 to transform to a gas, that is, by ashing. It is noted that cover 70 may be removed by grinding.

Preferably, in forming closing portion 52, an atmosphere in a treatment chamber is set to an atmosphere obtained by reducing a pressure of an ambient atmosphere. A pressure of the atmosphere is set preferably to be higher than 10⁻¹ Pa and lower than 10⁴ Pa. It is noted that this atmosphere may be an inert gas atmosphere. As an inert gas, for example, a noble gas such as He or Ar, a nitrogen gas, or a gas mixture of a noble gas and the nitrogen gas can be employed. In employing this gas mixture, a ratio of the nitrogen gas is set, for example, to 60%. In addition, a pressure in the treatment chamber is preferably not higher than 50 kPa and more preferably not higher than 10 kPa.

Since a construction other than the above is substantially the same as in the first to fourth embodiments described above, the same or corresponding elements have the same reference characters allotted and description thereof will not be repeated.

According to the present embodiment, as in the fourth embodiment, an effect resulting from closing of gap GP is achieved. In addition, in particular according to the present embodiment, gap GP can be closed without affecting a structure outside gap GP. Namely, composite substrate 82 having the surface of SiC substrates 11 to 13 as its surface can be obtained.

### Sixth Embodiment

In the present embodiment, manufacturing of a semiconductor device including composite substrate 81 (FIG. 14) will be described. For the sake of brevity of description, only SiC substrate 11 in a group of SiC substrates included in composite substrate 81 may be mentioned, however, other SiC substrates will be handled substantially similarly.

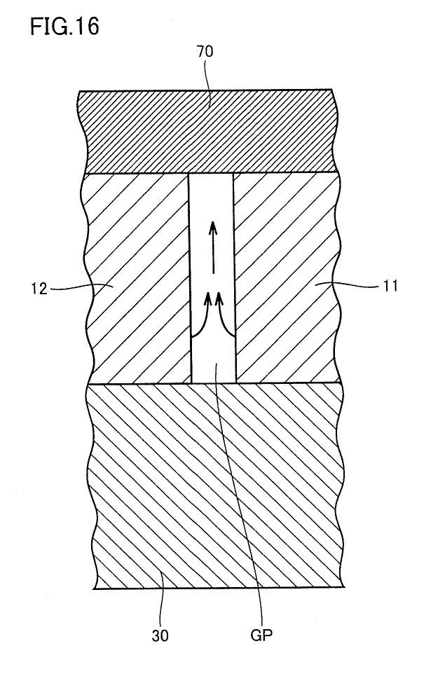

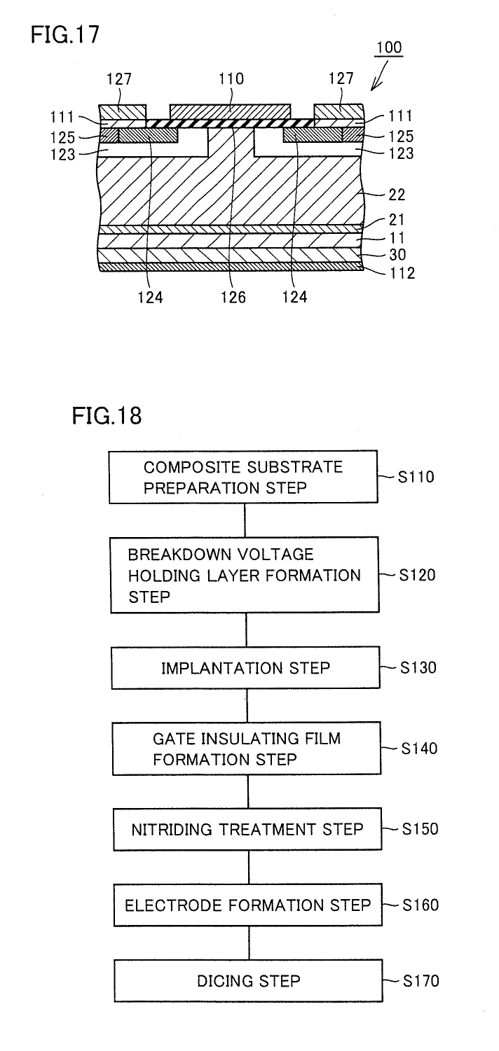

Referring to FIG. 17, a semiconductor device 100 in the present embodiment is a vertical DiMOSFET (Double Implanted Metal Oxide Semiconductor Field Effect Transistor), and it has base portion 30, SiC substrate 11, coating layer 21 (a buffer layer), a breakdown voltage holding layer 22, a p region 123, an n⁺ region 124, a p⁺ region 125, an oxide film 126, a source electrode 111, an upper source electrode 127, a gate electrode 110, and a drain electrode 112. Semiconductor device 100 has a two-dimensional shape (a shape when viewed from above in FIG. 17), for example, of a rectangle or a square having a side of a length not shorter than 2 mm.

Drain electrode 112 is provided on base portion 30, and buffer layer 21 is provided on SiC substrate 11. According to this arrangement, a region where flow of carriers is controlled by gate electrode 110 is arranged not on base portion 30 but on SiC substrate 11.

Base portion 30, SiC substrate 11, and buffer layer 21 have an n conductivity type. Concentration of an n-type conductive impurity in buffer layer 21 is, for example, 5×10¹⁷ cm⁻³. In addition, buffer layer 21 has a thickness, for example, of 0.5 μm.

Breakdown voltage holding layer 22 is formed on buffer layer 21 and composed of SiC having the n conductivity type. For example, breakdown voltage holding layer 22 has a thickness of 10 μm and concentration of the n-type conductive impurity of 5×10¹⁵ cm⁻³.

A plurality of p regions 123 having the p conductivity type are formed in a surface of this breakdown voltage holding layer 22, at a distance from one another. In the inside of p region 123, n⁺ region 124 is formed in a surface layer of p region 123. In addition, at a position adjacent to this n⁺ region 124, p⁺ region 125 is formed. Oxide film 126 is formed on breakdown voltage holding layer 22 exposed through the plurality of p regions 123. Specifically, oxide film 126 is formed to extend from n⁺ region 124 in one p region 123 over p region 123, breakdown voltage holding layer 22 exposed between two p regions 123, and the other p region 123 to n⁺ region 124 in the other p region 123. Gate electrode 110 is formed on oxide film 126. In addition, source electrode 111 is formed on n⁺ region 124 and p⁺ region 125. Upper source electrode 127 is formed on this source electrode 111.

A maximum value of nitrogen atom concentration in a region within 10 nm from an interface between oxide film 126 and n⁺ region 124, p⁺ region 125, p region 123, and breakdown voltage holding layer 22 each serving as the semiconductor layer is not lower than 1×10²¹ cm⁻³. Thus, mobility in particular in a channel region under oxide film 126 (a portion of p region 123 between n⁺ region 124 and breakdown voltage holding layer 22, which is in contact with oxide film 126) can be improved.

A method of manufacturing semiconductor device 100 will now be described.

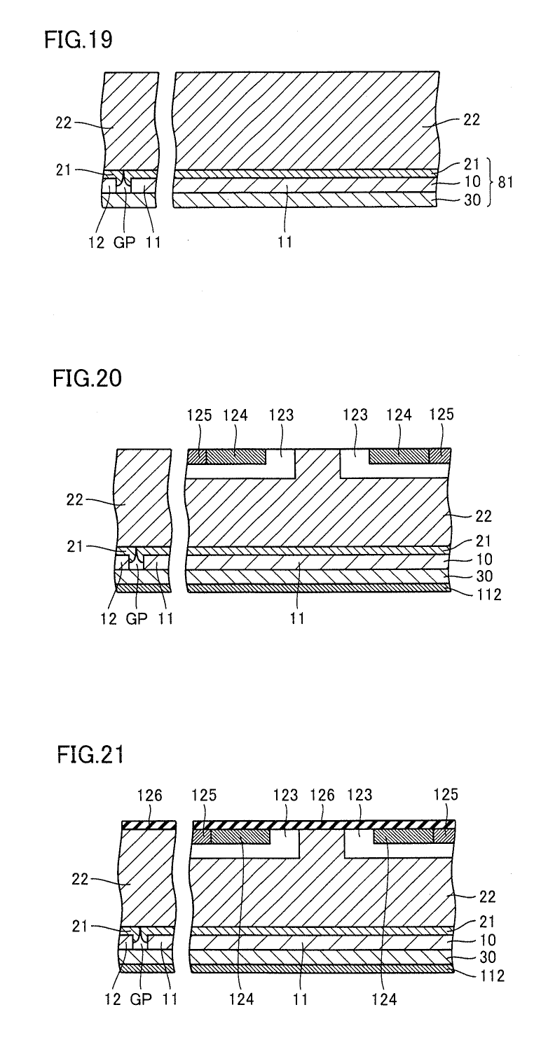

As shown in FIG. 19, initially, composite substrate 81 (FIG. 14) is prepared (FIG. 18: step S110). Preferably, the surface of coating layer 21 (the buffer layer) is polished. Buffer layer 21 is an epitaxial layer composed of silicon carbide having the n conductivity type and having a thickness, for example, of 0.5 μm. Concentration of a conductive impurity in buffer layer 21 is set, for example, to 5×10¹⁷ cm⁻³.

Then, breakdown voltage holding layer 22 is formed on buffer layer 21 (FIG. 18: step S120). Specifically, a layer composed of silicon carbide having the n conductivity type is formed with an epitaxial growth method. Breakdown voltage holding layer 22 has a thickness, for example, of 10 μm. Concentration of an n-type conductive impurity in breakdown voltage holding layer 22 is set, for example, to 5×10¹⁵ cm⁻³.

As shown in FIG. 20, as a result of an implantation step (FIG. 18: step S130), p region 123, n⁺region 124, and p⁺region 125 are formed as follows.

Initially, as a p-type conductive impurity is selectively implanted into a part of breakdown voltage holding layer 22, p region 123 is formed. Then, as an n-type conductive impurity is selectively implanted into a prescribed region, n⁺region 124 is formed. In addition, as a p-type conductive impurity is selectively implanted into a prescribed region, p⁺region 125 is formed. It is noted that selective implantation of an impurity is carried out, for example, by using a mask formed from an oxide film.

After such an implantation step, activation annealing treatment is performed. For example, in an argon atmosphere, annealing for 30 minutes at a heating temperature of 1700° C. is carried out.

As shown in FIG. 21, a gate insulating film formation step (FIG. 18: step S140) is performed. Specifically, oxide film 126 is formed to cover breakdown voltage holding layer 22, p region 123, n⁺region 124, and p⁺region 125. This formation may be achieved by dry oxidation (thermal oxidation). Conditions for thermal oxidation are, for example, a heating temperature of 1200° C. and a heating time period of 30 minutes.

Thereafter, a nitriding treatment step (FIG. 18: step S150) is performed. Specifically, annealing treatment in a nitric oxide (NO) atmosphere is performed. For example, conditions in this treatment are such that a heating temperature is set to 1100° C. and a heating time period is set to 120 minutes. Consequently, nitrogen atoms are introduced in the vicinity of the interface between each of breakdown voltage holding layer 22, p region 123, n⁺ region 124, and p⁺ region 125 and oxide film 126.

After this annealing step using nitric oxide, annealing treatment using an argon (Ar) gas which is an inert gas may further be performed. For example, conditions in this treatment are such that a heating temperature is set to 1100° C. and a heating time period is set to 60 minutes.

Then, in an electrode formation step (FIG. 18: step S160), source electrode 111 and drain electrode 112 are formed as follows.

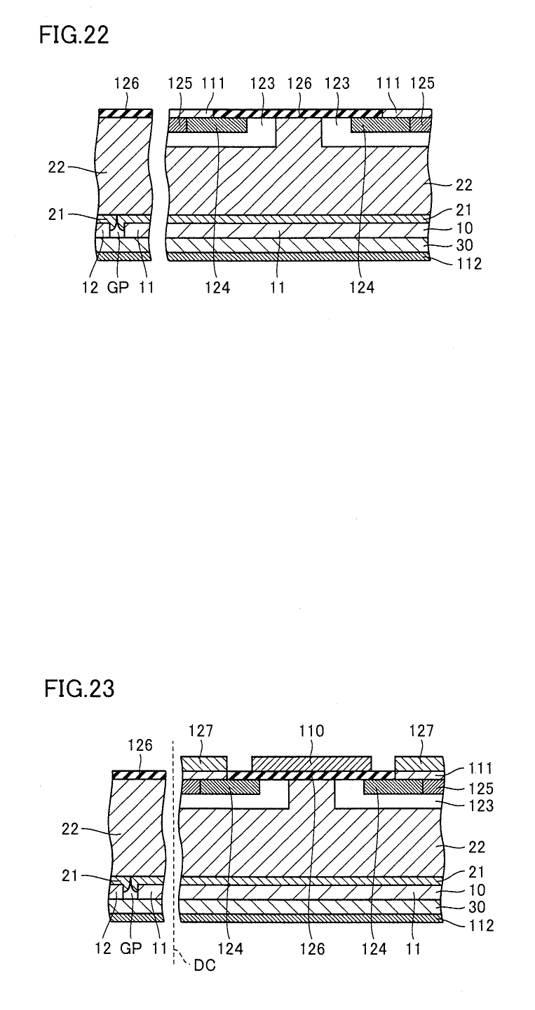

As shown in FIG. 22, a resist film having a pattern is formed on oxide film 126 with photolithography. Using this resist film as a mask, a portion of oxide film 126 located on n⁺ region 124 and p⁺ region 125 is etched away. Thus, an opening is formed in oxide film 126. Then, a conductor film is formed in this opening so as to be in contact with each of n⁺ region 124 and p⁺ region 125. Then, by removing the resist film, the portion of the conductor film above that has been located on the resist film is removed (lifted off). This conductor film may be a metal film, and it is composed, for example, of nickel (Ni). As a result of this lift-off, source electrode 111 is formed.

It is noted that heat treatment for alloying is preferably performed here. For example, in an atmosphere of an argon (Ar) gas representing an inert gas, heat treatment for 2 minutes at a heating temperature of 950° C. is performed.

Referring to FIG. 23, upper source electrode 127 is formed on source electrode 111. In addition, gate electrode 110 is formed on oxide film 126. Moreover, drain electrode 112 is formed on the back surface of composite substrate 81.

Then, in a dicing step (FIG. 18: step S170), dicing as shown with a dashed line DC is performed. A plurality of semiconductor devices 100 (FIG. 17) are thus cut.

In a variation of the present embodiment, other composite substrates 71 to 73 or 82 described above may be employed instead of composite substrate 81 (FIG. 14). In this case, steps similar to the above are performed after buffer layer 21 is formed.

A configuration in which conductivity types are interchanged, that is, a configuration in which p-type and n-type are interchanged, with respect to the configuration described above, can also be employed. In addition, though a vertical DiMOSFET has been exemplified, other semiconductor devices may be manufactured by using the composite substrate according to the present invention, and for example, a RESURF-JFET (Reduced Surface Field-Junction Field Effect Transistor) or a Schottky diode may be manufactured.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

11 to 13 SiC substrate (first to third single-crystal silicon carbide substrates); 11v, 12v SiC substrate (first and second single-crystal silicon carbide substrates); 14 to 22 SiC substrate (single-crystal silicon carbide substrate); 21 coating layer (buffer layer); 22 breakdown voltage holding layer; 30 base portion; 51, 52 closing portion; 70 cover; 71 to 73, 81, 82 composite substrate; 100 semiconductor device; and GP gap.

1. A composite substrate, comprising:
a base portion;
a first single-crystal silicon carbide substrate provided on said base portion and having a first side extending from a first vertex having a first angle in planar view;
a second single-crystal silicon carbide substrate provided on said base portion and having a second side extending from a second vertex having a second angle, a sum of said first angle and said second angle being 180° in planar view; and
a third single-crystal silicon carbide substrate provided on said base portion and having a third side connecting third and fourth vertices (P3, P4) to each other in planar view,
said first vertex and said second vertex abutting each other such that said first side and said second side are aligned, at least a part of said first side abutting on said third side, and at least a part of said second side abutting on said third side, and
a portion of said base portion facing each of said first to third single-crystal silicon carbide substrates being a portion epitaxially grown on said first to third single-crystal silicon carbide substrates.

2. The composite substrate according to claim 1, wherein
a gap is provided among said first to third single-crystal silicon carbide substrates, and
said composite substrate further comprises a closing portion closing said gap.

3. The composite substrate according to claim 2, wherein
said closing portion closes said gap, within said gap.

4. The composite substrate according to claim 2, further comprising a coating layer formed on said first to third single-crystal silicon carbide substrates, wherein
said coating layer includes said closing portion.

5. The composite substrate according to claim 2, wherein
said closing portion is made of silicon carbide.
